(19) United States
(12) Patent Application Publication
(10) Pub. No.: US 2014/0376162 A1
(43) Pub. Date: Dec. 25, 2014

(54) DISPLAY DEVICE AND METHOD FOR MANUFACTURING THE DISPLAY DEVICE

(71) Applicant: Samsung Display Co., Ltd., Yongin-City (KR)

(72) Inventors: Sang hyun LIM, Andong-si (KR); Sung Sang AHN, Seoul (KR)

(73) Assignee: Samsung Display Co., Ltd., Yongin-City (KR)

(21) Appl. No.: 14/145,762

(22) Filed: Dec. 31, 2013

(30) Foreign Application Priority Data
Jun. 24, 2013 (KR) 10-2013-0072531

(51) Int. Cl. H05K 5/00

(52) U.S. Cl. CPC H05K 5/0017
USPC 361/679.01; 29/592.1

(57) ABSTRACT

A display device may include a display panel, a cover member, and a protective layer. The display panel may include a display portion that is configured to display an image according to a signal. The cover member may overlap the display panel, may include a cover portion, and may have a through hole that extends through the cover portion. The protective layer may be configured to cover the through hole.

### CROSS-REFERENCE TO RELATED APPLICATION

This U.S. non-provisional patent application claims priority and benefit under 35 U.S.C. §119 of Korean Patent Application No. 10-2013-0072531, filed on Jun. 24, 2013, the contents of which are incorporated herein by reference.

### BACKGROUND

1. Field of the Invention

The present invention relates to a display device and a method for manufacturing the display device.

2. Description of the Related Art

In general, a display device may include a display panel and a cover window (or cover member). The display panel may include driving devices for display images according to input signals. The cover window may be attached onto the display panel to protect the display panel from an external environment. The images may be displayed through the cover window.

### SUMMARY

Embodiments of the present invention may be related to a display device that includes a cover member substantially uniformly attached to a display panel.

Embodiments of the invention may be related to a method for manufacturing the display device.

Embodiments of the invention may be related to a display device that may include a display panel, a cover member, and a protective layer. The display panel may include a first display portion that is configured to display a first image according to a first signal. The cover member may overlap the display panel, may include a first cover portion, and may have a first through hole that extends through the first cover portion. The protective layer may be configured to close an opening of the first through hole.

A boundary the opening of the first through hole may be configured to overlap the first image and/or the first display portion.

The first cover portion may be substantial flat.

The first cover portion may be substantial curved.

The display panel may include a second display portion, which may be configured to display a second image when the first display portion displays the first image.

An extension direction of the first through hole may not be perpendicular to a display surface of the second display portion that is configured to display the second image.

An extension direction of the first through hole may be at an obtuse angle with respect to a display surface of the second display portion that may be configured to display the second image.

An extension direction of the first through hole may be parallel to a display surface of the second display portion that may be configured to display the second image.

The cover member may further include a second cover portion and may further have a second through hole that extends through the second cover portion. An extension direction of the second through hole may not be parallel to an extension direction of the first through hole.

The extension direction of the second through hole may be at an obtuse angle with respect to the extension direction of the first through hole.

The extension direction of the second through hole may be perpendicular to the extension direction of the first through hole.

The display panel may include a second display portion, which may be configured to display a second image when the first display portion displays the first image. A boundary of an opening of the second through hole may be configured to overlap the second image and/or the second display portion.

The display panel may include a non-display portion that may be adjacent to the first display portion. A boundary of an opening of the second through hole may overlap the non-display area.

The display panel further may include a non-display portion that may be adjacent to the first display portion. The non-display portion may overlap a boundary of the opening of the first through hole.

An extension direction of the first through hole may not be perpendicular to a display surface of the first display portion that may be configured to display the first image.

A portion of the protective layer may be disposed inside the first through hole.

A diameter of the opening of the first through hole may be equal to or less than 5 micrometers

Embodiments of the invention may be related to a method for manufacturing a display device. The method may include the following steps: forming a cover member, the cover member including a first cover portion and having a first through hole that extends through the first cover portion; pushing a first set of air to exit through the first through hole when combining a display panel and the cover member, the display panel including a display portion that may be configured to display an image according to a signal; and disposing a protective layer to close an opening of the first through hole.

The method may include the following steps: disposing a combination of the display panel and the cover member on a stage that includes a conduit; and extracting a second set of air through the first through hole and the conduit.

The method may include the following steps: letting a second set of air exit through a second through hole when combining the display panel and the cover member, The cover member includes a second cover portion, The second through hole extends through the second cover portion, and wherein an extension direction of the second through hole may be not parallel to an extension direction of the first though hole.

A boundary the opening of the first through hole may overlap the display portion during the pushing.

The display panel may include a non-display portion that may be adjacent to the display portion. A boundary the opening of the first through hole may overlap the non-display portion during the pushing. Embodiments of the invention may be related to a display device that may include the following elements: a cover member that includes at least one through hole; a display panel disposed on an inner surface of the cover member; and a protective layer disposed on an outer surface of the cover member to cover the through hole.

The display panel may be an organic light emitting display panel or a flexible display panel.

The inner surface of the cover member includes a first surface substantially in parallel to a first direction and at least one second surface bent from the first surface and extended in a second direction different from the first direction.

The first direction may be substantially perpendicular to the second direction.

The inner surface of the cover member includes a curved surface.

The through hole has a circular shape when viewed in a cross section and the circular shape has a diameter equal to or smaller than about 5 micrometers.

The cover member includes a synthetic resin.

The protective layer includes a heat-curable resin or a light-curable resin.

The protective layer further includes a silicon-based compound or a fluorine-based compound.

The through hole may be provided in a plural number and the protective layer may be partially filled in the through holes.

The protective layer may be a synthetic resin film.

Embodiments of the invention may be related to a display device that may include the following elements: a cover member that includes a plane surface portion and at least one bending portion and provided with a plurality of through holes formed penetrating through the plane surface portion and the bending portion; a flexible display panel disposed on one surface of the cover member to cover the through holes; and a protective layer disposed on the other surface of the cover member.

Embodiments of the invention may be related to a method for manufacturing a display device. The method may include the following steps: forming a cover member that includes at least one through hole formed therethrough; attaching a display panel to one surface of the cover member; and forming a protective layer on the other surface of the cover member to cover the other surface of the cover.

The through hole may be formed by irradiating a laser beam onto the cover member.

The attaching of the display panel to the one surface of the cover member includes providing the cover member on a vacuum stage, pre-attaching the display panel to the one surface of the cover member, and sucking an air between the cover member and the display panel to attach the display panel to the one surface of the cover member.

The pre-attaching of the display panel may be performed using a roller.

The forming of the protective layer may be performed using a spraying method, a spin coating method, a slit coating method, or a deposition method.

The forming of the protective layer includes providing a synthetic resin film on the other surface of the cover member and attaching the synthetic resin film and the cover member.

According to embodiments of the invention, air existing between the cover member and the display panel may be exit through the through hole. Thus, the adhesion between the cover member and the display panel may be substantially robust. Bubbles or wrinkles, which might be caused by the air, may be prevented or minimized in the display device, and thus a satisfactory quality of the display device may be provided.

According to embodiments of the invention, air between the cover member and the display panel may be vented and minimized. Therefore, the display panel may be substantially uniformly attached to the cover member, which may have one or more of various shapes.

### BRIEF DESCRIPTION OF THE DRAWINGS

FIG. 1 is a perspective view illustrating a display device according to an embodiment of the present invention;

FIG. 2 is a cross-sectional view illustrating the display device illustrated in FIG. 1 according to an embodiment of the present invention;

FIG. 3 is a cross-sectional view illustrating an area AA indicated in FIG. 2 or an analogous area according to an embodiment of the present invention;

FIG. 4 is a cross-sectional view illustrating an area AA indicated in FIG. 2 or an analogous area according to an embodiment of the present invention;

FIG. 5 is a perspective view illustrating a display device according to an embodiment of the present invention;

FIG. 6 is a cross-sectional view illustrating the display device illustrated in FIG. 5 according to an embodiment of the present invention;

FIG. 7 is a cross-sectional view illustrating an area AA′ indicated in FIG. 6 or an analogous area;

FIG. 8 is a cross-sectional view illustrating a display device according to an embodiment of the present invention;

FIG. 9 is a flowchart illustrating a method for manufacturing a display device according to an embodiment of the present invention; and

FIGS. 10A to 10G are cross-sectional views illustrating a method for manufacturing a display device according to an embodiment of the present invention.

### DETAILED DESCRIPTION

In this description, when an element or layer is referred to as being “on”, “connected to”, or “coupled to” another element or layer, it can be directly on, directly connected to, or directly coupled to the other element or layer, or at least one intervening element or layer may be present. When an element is referred to as being “directly on”, “directly connected to”, or “directly coupled to” another element or layer, there are no intended intervening elements or layers (except possible environmental elements, e.g., air) present.

Like numbers may refer to like elements. The term “and/or” may include any and all combinations of one or more of the associated items.

Although the terms “first”, “second”, etc. may be used herein to describe various elements, components, regions, layers, and/or sections, these elements, components, regions, layers and/or sections should not be limited by these terms. These terms are used to distinguish one element, component, region, layer, or section from another region, layer, or section. Thus, a first element, component, region, layer, or section discussed below could be termed a second element, component, region, layer, or section without departing from the teachings of the present invention. The description of an element as a “first” element may not require or imply the presence of a second element or other elements. The terms “first”, “second”, etc. may also be used herein to differentiate different categories of elements. For conciseness, the terms “first”, “second”, etc. may represent “first-type (or first-category)”, “second-type (or second-category)”, etc., respectively.

Spatially relative terms, such as “beneath”, “below”, “lower”, “above”, “upper”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be oriented in various ways (e.g., rotated by 90 degrees or disposed at other orientations) and the spatially relative descriptors may be interpreted accordingly.

The terminology used herein is for the purpose of describing particular embodiments and is not intended to be limiting of the invention. As used herein, the singular forms, “a”, “an”, and “the” may include the plural forms as well, unless the context clearly indicates otherwise. The terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. Terms, such as those defined in commonly used dictionaries, should be interpreted as having meanings that are consistent with their meanings in the context of the relevant art and should not be interpreted in an idealized or overly formal sense unless expressly so defined herein.

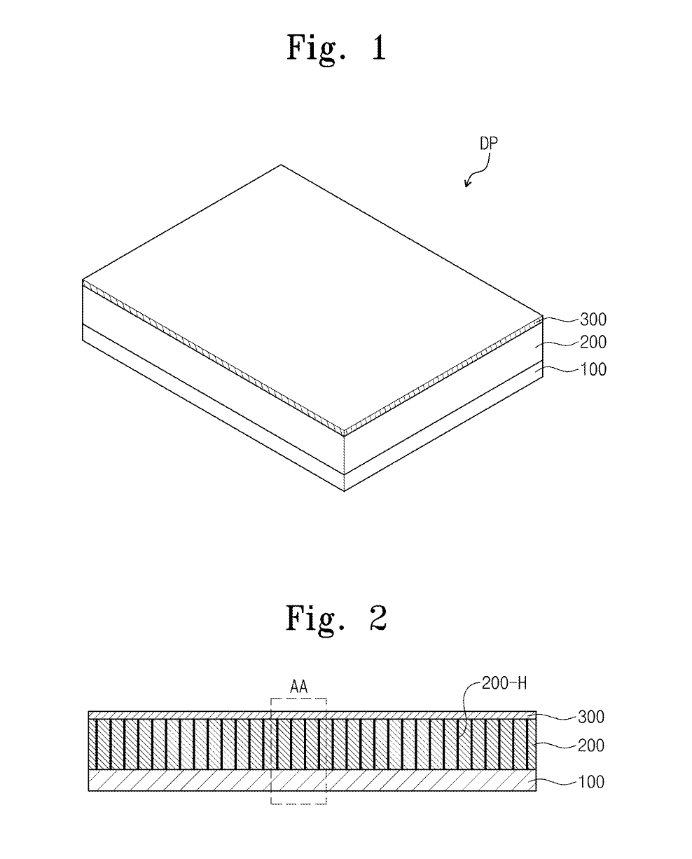

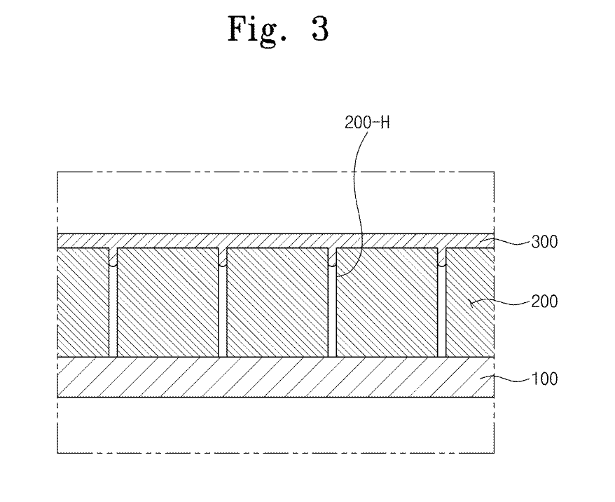

FIG. 1 is a perspective view illustrating a display device DP according to an embodiment of the present invention. FIG. 2 is a cross-sectional view illustrating the display device DP according to an embodiment of the present invention. Referring to FIG. 1, the display device DP includes a display panel 100, a cover member 200, and a protective layer 300.

Referring to FIGS. 1 and 2, the display panel 100 overlaps the cover member 200. The display panel 100 may include a plurality of signal lines and a plurality of pixels connected to the signal lines. Each pixel may include a capacitor, a transistor, and a display member.

The signal lines may apply electrical signals to the pixels. The pixels may display an image in response to the electrical signals.

The display panel 100 may be or may include at least one of various display panels, such as a liquid crystal display panel, an electophoretic display panel, a light emitting diode display panel, etc. In an embodiment, the display panel 100 may be an organic light emitting display panel.

As illustrated in FIG. 1, the cover member 200 is disposed on the display panel 100 to cover the display panel 100. The cover member 200 may protect the display panel 100.

The cover member 200 may be substantially transparent and may transmit the image displayed on the display panel 100. The cover member 200 may include at least one of glass, synthetic resin, and ceramic.

As illustrated in FIG. 2, the cover member 200 includes at least one through hole 200-H (or conduit 200-H) that penetrates through the cover member 200 and/or extends from a first side of the cover member 200 to a second side of the cover member 200.

The through hole 200-H serves as a path through which air existing between the cover member 200 and the display panel 100 may exit when the cover member 200 and the display panel 100 are combined. In an embodiment, the cover member 200 includes a substantial amount of through holes 200-H, such that the amount of air that is trapped between the cover member 200 and the display panel 100 may be minimized. Advantageously, the cover member 200 may be substantially uniformly attached to the display panel 100.

A size of the through hole 200-H may influence adhesion between the cover member 200 and the display panel 100 and/or may influence image display quality associated with the display device DP. For example, if the size of the through holes 200-H is substantially large, air that exists between the display panel 100 and the cover member 200 may be substantially released when the display panel 100 and the cover member 200 are combined, such that the adhesion may be substantially uniform. Nevertheless, large through holes 200-H may be substantially conspicuous to human eyes. In an embodiment, one or more through holes 200-H may be disposed in a display area of the display device DP, i.e., in a portion of the cover member 200 that overlaps the display area of the display panel 100. If the through holes were too large, the image display quality associated with the display device DP might be unsatisfactory to the viewer.

The through holes 200-H may have a size that is suitable for substantially uniformly combining the cover member 200 and the display panel 100 and for maintaining satisfactory image display quality associated with the display device DP. In an embodiment, a through hole 200-H may have a circular-shaped cross-section with a diameter of about 5 micrometers. The through holes 200-H may be substantially uniformly distributed in (at least a portion of) the cover member 200.

As illustrated in FIGS. 1 and 2, the protective layer 300 is disposed on the cover member 200. The protective layer 300 may cover (and seal) the through holes 200-H of the cover member 200.

The protective layer 300 may protect the outside of the cover member 200. The protective layer 300 is formed of a substantially transparent material such that the image displayed by the display panel 100 may be transmitted through the protective layer 300. In an embodiment, the protective layer 300 may include a heat-curable and/or light-curable resin.

The protective layer 300 has an antifouling or anti-contamination property for preventing surfaces of the protective layer 300 from being contaminated. The protective layer 300 may include a material having a fingerprint prevention function and/or a diffuse reflection function. In an embodiment, the protective layer 300 may include a silicon-based compound and/or a fluorine-based compound.

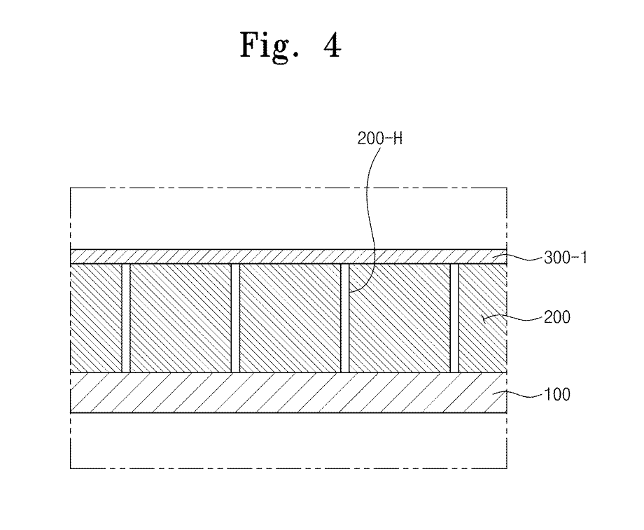

FIG. 3 is a cross-sectional view illustrating an area AA indicated in FIG. 2 according to an embodiment of the present invention.

Referring to FIG. 3, the cover member 200 may include a plurality of through holes 200-H. The protective layer 300 is formed using a curable resin provided in a liquid state. The liquid material including the curable resin is coated on the outer surface of the cover member 200 and is cured to form the protective layer 300.

A portion of the liquid material may flow into the through holes 200-H. Therefore, portions of the protective layer 300 may be disposed inside the through holes 200-H. As a result, a contact area between the protective layer 300 and the cover member 200 may be substantially large. Advantageously, the adhesion between the protective layer 300 and the cover member 200 may be substantially secure. In an embodiment, the portions of the protective layer 300 partially fill the through holes 200-H without completely filling the through holes 200-H.

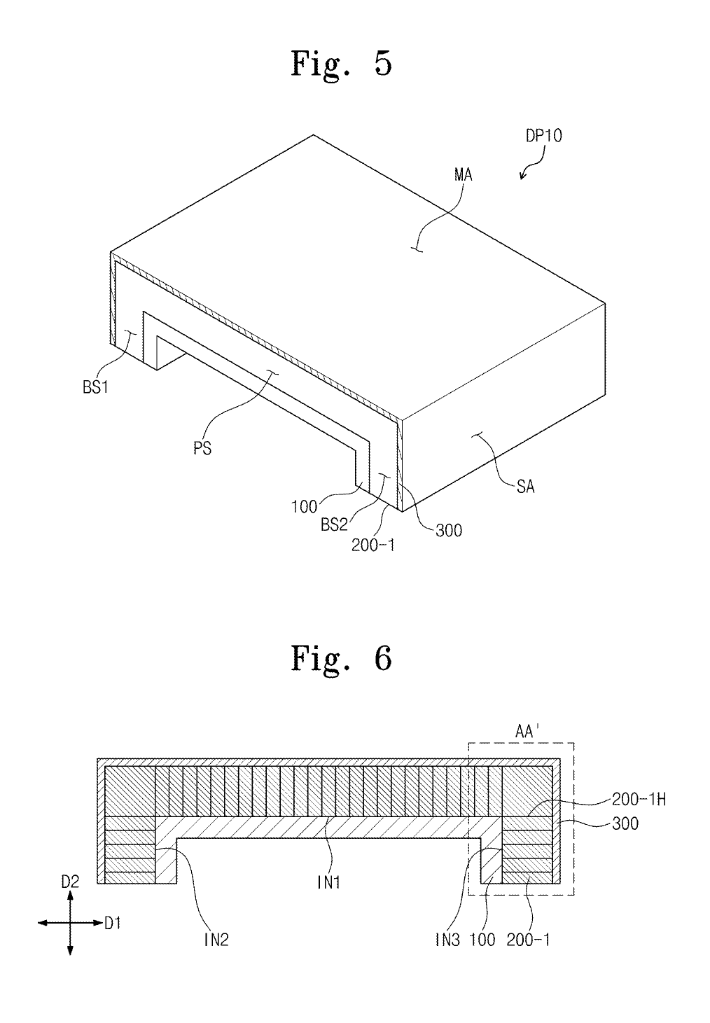

FIG. 4 is a cross-sectional view illustrating an area AA indicated in FIG. 2 according to an embodiment of the present invention.

Referring to FIG. 4, the display device DP may include a protective film 300-1 instead of or in addition to the protective layer 300 illustrated in FIG. 3. The protective film 300-1 may substantially cover (and seal) the through holes 200-H without substantially entering the through holes 200-H. The protective film 300-1 may include one or more films, such as a synthetic resin film or a plurality of stacked synthetic resin films. The protective film 300-1 may provide satisfactory surface uniformity for the display device DP.

In an embodiment, the display device DP may include an adhesive layer that is disposed between the protective film 300-1 and the cover member 200. The adhesion between the protective film 300-1 and the cover member 200 may be substantially reinforced by the adhesive layer.

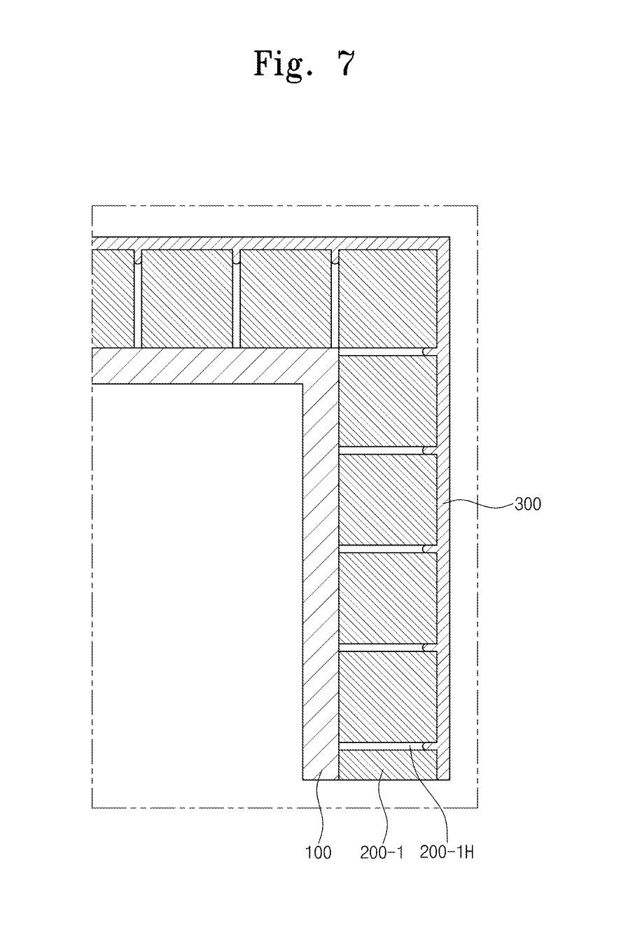

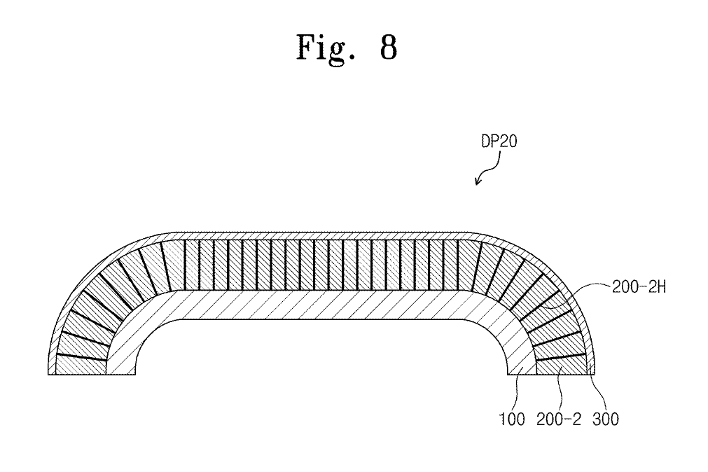

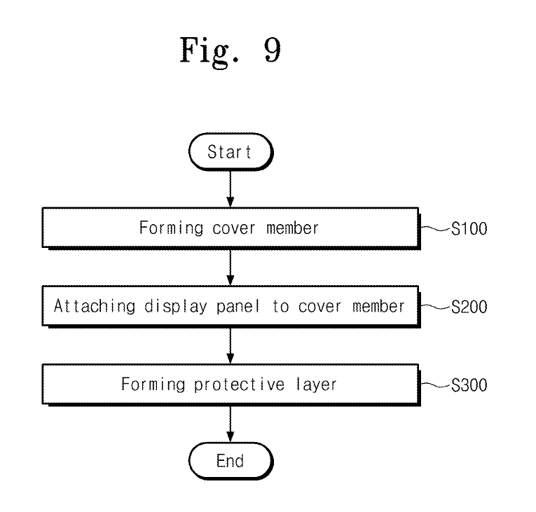

FIG. 5 is a perspective view illustrating a display device DP10 according to an embodiment of the present invention. FIG. 6 is a cross-sectional view illustrating the display device DP10 according to an embodiment of the present invention. FIG. 7 is a cross-sectional view illustrating an area AA′ indicated in FIG. 6. In FIGS. 1 to 7, same reference numerals may denote elements that have analogous or substantially identical properties. Description of elements that have analogous or identical properties may not be repeated.

Referring to FIGS. 5 to 7, the display device DP10 includes a display panel 100, a cover member 200-1 including a curved surface, and a protective layer 300. The cover member 200-1 includes a plane surface portion PS (or front portion PS) and at least one bending portion (or side portion) that is connected to the plane surface portion PS. An orientation of the plane surface portion PS is different from an orientation of the bending portion. In an embodiment, the bending portion may extend in a direction not parallel to (e.g., a direction perpendicular to) an extension direction of the plane surface portion. In an embodiment, the cover member 200-1 includes the plane surface portion PS, a first bending portion BS1 (or first side portion BS1), and a second bending portion BS2 (or second side portion BS2).

As illustrated in FIG. 5, the display device DP10 includes a main area MA (or main portion MA) and at least one secondary area SA (or secondary portion SA). An orientation of the main area MA may be different from an orientation of the secondary area SA.

The main area MA may correspond to and/or overlap a main display area of the display panel 100, which displays a main image. The main area MA corresponds to and overlaps the plane surface portion PS.

A secondary area SA may correspond to and/or overlap a secondary display area of the display panel 100. An additional image (or secondary image) may be displayed in the secondary area SA.

In an embodiment, the main area MA may display a first view (e.g., a front view) of an object, and the secondary area SA may display a second view (e.g., a side view) of the object. Therefore, the display device DP10 may display a substantially three-dimensional image of the object.

In an embodiment, an image of a first object may be displayed in the main area MA, and an image of a second object may be displayed in the secondary area SA. The second object may be substantially different from the first object. In other words, the display device DP10 may display images of different objects simultaneously in different directions and/or orientations.

In an embodiment, the secondary area SA may overlap a non-display area of the display panel 100. Various members, e.g., an input button used for controlling the display device DP10, driving wirings, etc., may be disposed in the secondary area SA. The secondary area SA may be covered by an outer member (not illustrated) that serves as a housing of the display device DP10.

The display device DP10 may include a plurality of secondary areas SA. Two secondary areas may correspond to and/or overlap the first bending portion BS1 or the second bending portion BS2.

Referring to FIG. 6, the cover member 200-1 includes a plurality of inner surfaces. The inner surfaces include a first surface IN1 and at least one bending surface (or at least one side surface) connected to the first surface IN1. The at least one bending surface may include a second surface IN2 and a third surface IN3.

As illustrated in FIGS. 5 and 6, the first surface IN1 is substantially in parallel to (or extends in) a first direction D1. The first surface IN1 may correspond to (and/or may represent) an inner surface of the plane surface portion PS. The first surface IN1 may correspond to (and/or may belong to) the main area MA of the display device DP10.

The surfaces IN2 and IN3 may be connected to the first surface IN1 and may extend in a second direction D2 that is different from the first direction D1. Each of the directions D1 and D2 may be substantially perpendicular to the first surface IN1. The second surface IN2 may correspond to (and/or may represent) an inner surface of the first bending portion BS1, and the third surface IN3 may correspond to (and/or may represent) an inner surface of the second bending portion BS2 The second surface IN2 and the third surface IN3 may respectively correspond to (and/or belong to) the secondary areas.

In an embodiment, the display panel 100 may be a flexible display panel. The display panel 100 may be disposed inside the cover member 200-1 and may be attached to one or more of the surfaces IN1, IN2, and IN3.

As illustrated in FIG. 6, the cover member 200-1 includes at least one through hole 200-1H formed therethrough and extending in at least one of the directions D1 and D2. In an embodiment, at least one through hole 200-1H may be formed through each of the surfaces IN1, IN2, and IN3. For example, the cover member 200-1 may include a first through hole 200-1H, a second through hole 200-1H, and a third through hole 2001H. The first through hole 200-1H may be formed through the portion PS and may extend in the second direction D2. The second through hole 200-1H and the third through hole 200-1H may be formed through the portions BS1 and BS2, respectively, and may extend in the first direction. The through holes 200-1H may release air when the display panel 100 and the cover member 200-1 are combined. Advantageously, the display panel 100 may be uniformly attached to the surfaces IN1, IN2, and IN3.

Referring to FIG. 7, the protective layer 300 may be formed by coating a material in a liquid state on the outer surface of the cover member 200-1 The protective layer 300 may protects surface of the plane surface portion PS and the bending portions BS1 and BS2. In an embodiment, a configuration (e.g., a thickness and/or a material) of a portion of the protective layer 300 formed on the plane surface portion PS may be different from a configuration (e.g., a thickness and/or a material) of a portion of the protective layer 300 formed on the first portion BS1 and/or the second bending portion BS2.

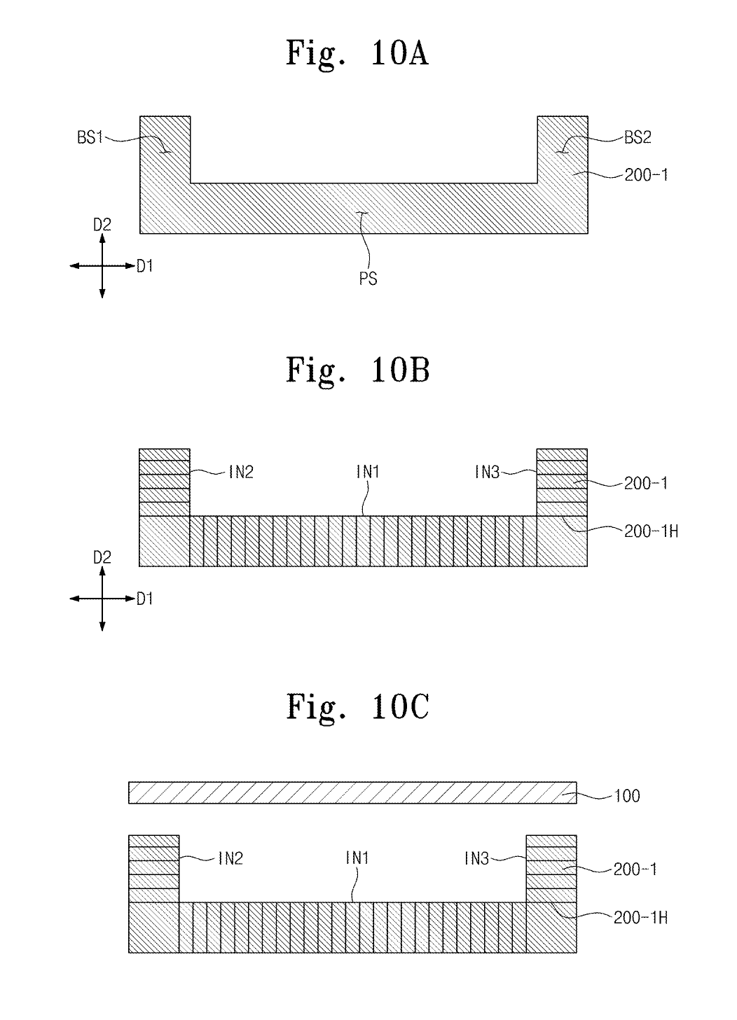

FIG. 8 is a cross-sectional view illustrating a display device DP20 according to an embodiment of the present invention. In FIGS. 1 to 8, same reference numerals may denote elements that have analogous or substantially identical properties. Description of elements that have analogous or identical properties may not be repeated

Referring to FIG. 8, the display device DP20 includes a cover member 200-2 that includes at least one curved surface. The cover member 200-2 includes an inner surface and an outer surface. The inner surface of the cover member 200-2 may include an inner curved surface and an inner flat surface, and the outer surface of the cover member 200-2 may include an outer curved surface and an outer flat surface.

The cover member 200-2 may include at least one through hole 200-2H that extends from the inner curved surface to the outer curved surface. The cover member 200-2 may include at least one through hole 200-2H that extends from the inner flat surface to the outer flat surface. The through hole(s) 200-2H may release air existing between the cover member 200-2 and the display panel 100 when the cover member 200-2 and the display panel 100 are combined.

In an embodiment, the display panel 100 may be a flexible display panel. The display panel 100 may be disposed along the inner surface of the cover member 200-2 and may be attached to the inner surface of the cover member 200-2. In an embodiment, the cover member 200-2 may include the through holes 200-2H in both a flat portion of the cover member 200-2 and a curved portion of the cover member 200-2. Advantageously, the display panel 100 may be substantially securely attached to the cover member 200-2.

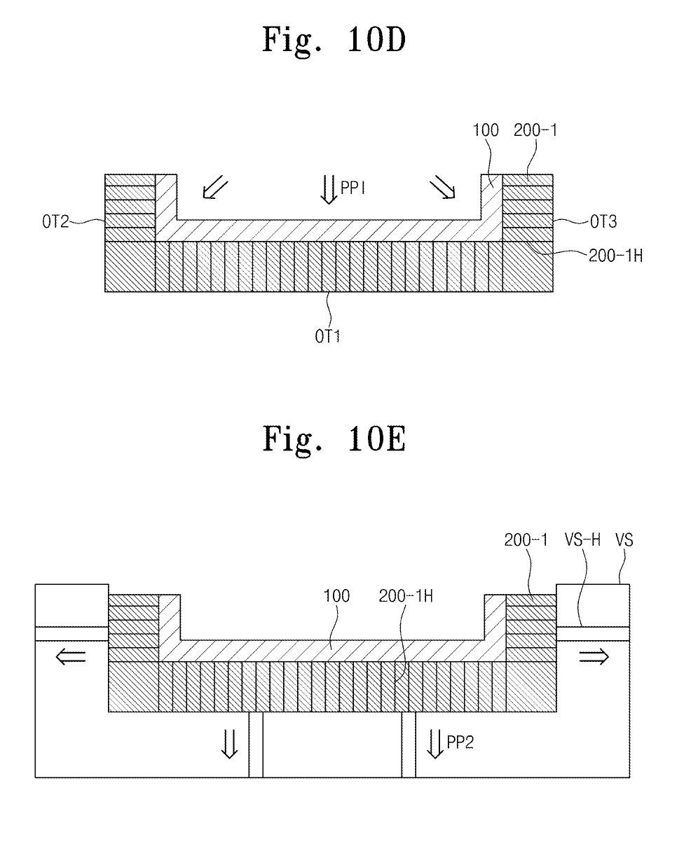

FIG. 9 is a flowchart illustrating a method for manufacturing a display device according to an embodiment of the present invention.

Referring to FIG. 9, the method includes providing a cover member (in step S100), attaching at least one surface of a display panel to at least one surface, e.g., at least one inner surface, of the cover member (in step S200), and forming a protective layer on the other surface(s), e.g., at least one outer surface, of the cover member to cover the other surface(s) of the cover member (in step S300).

In the providing of the cover member (S100), one or more through holes may be formed through the cover member. The through hole(s) may be formed by irradiating one or more laser beams onto the cover member.

The attaching of the at least one surface of the display panel to the at least one surface of the cover member (S200) may include providing the cover member on a support stage (e.g., vacuum stage that performs vacuum suction and/or vacuum venting), pre-attaching the cover member to the display panel, and attaching the cover member to the display panel.

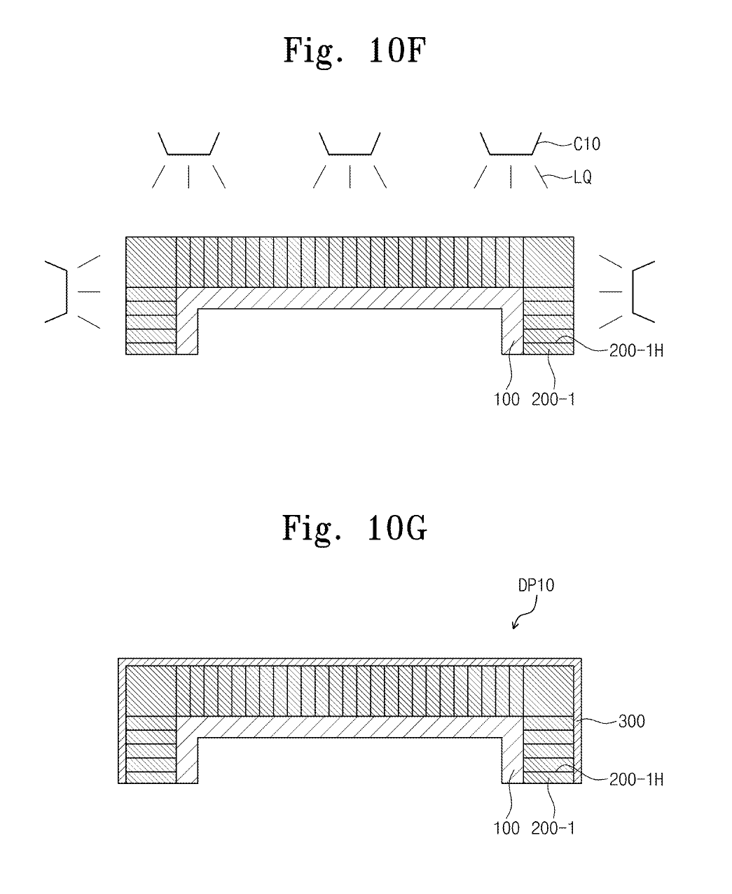

FIGS. 10A to 10G are cross-sectional views illustrating a method for manufacturing a display device according to an embodiment of the present invention. As an example, the display device may be the display device DP 10 discussed with reference to FIGS. 5 to 7.

The cover member 200-1 includes the plane surface portion PS and the at least one bending portion. The plane surface portion PS is disposed to be substantially in parallel to (or to extend in) the first direction D1. The cover member 200-1 includes the bending portions BS1 and BS2, which may be bent with respect to the plane surface portion PS and may extend in the second direction D2.

The cover member 200-1 may be formed using one or more of various methods, e.g., an injection molding, a compression molding method, an extrusion pressing method, a blow molding method, etc. In an embodiment, formation of the cover member 200-1 may include cutting a piece of glass material.

Referring to FIG. 10B, the inner surfaces of the cover member 200-1 may include the first surface IN1, the second surface IN2, and the third surface IN3.

The first surface IN1 corresponds to the inner surface of the plane surface portion PS. The surfaces IN2 and IN3 correspond to the inner surfaces of the bending portions BS1 and BS2, respectively. Each of the surfaces IN2 and IN3 may be bent with respect to the first surface IN1 at a predetermined angle, e.g., 90 degrees.

As illustrated in FIG. 10B, the cover member 200-1 includes at least one through hole 200-1H formed therethrough. The cover member 200-1 may include a plurality of through holes 200-1H, wherein the through holes 200-1H may be spaced apart from each other at substantially regular (or constant) intervals. In an embodiment, some through holes 200-1H may not be spaced at constant intervals. A plurality of through holes 200-1H may be formed through each of the surfaces IN1, IN2, and IN3 and through each of the portions PS, BS1, and BS2. For example, the cover member 200-1 may include a first plurality of through holes 200-1H, a second plurality of through holes 200-1H, and a third plurality of through holes 2001H. The first plurality of through holes 200-1H may be formed through the portion PS and may extend in the second direction D2. The second plurality of through holes 200-1H and the third plurality of through holes 200-1H may be formed through the portions BS1 and BS2, respectively, and may extend in the first direction.

The through holes 200-1H may be formed through various methods. In an embodiment, the through holes 200-1H are formed by irradiating laser beams onto the cover member 200-1. In an embodiment, the through holes 200-1H may be substantially simultaneously formed using a mask in which transmission areas (e.g., for a light or an etchant) corresponding to the through holes are defined.

Referring to FIG. 10C, the display panel 100 is disposed above the inner surfaces of the cover member 200-1. In an embodiment, the display panel 100 may be a flexible display panel, and the display panel 100 may substantially conform to a shape defined by the inner surfaces of the cover member 200-1 when being attached to the inner surfaces of the cover member 200-1.

Referring to FIG. 10D, an external pressure PP1 is applied to the display panel 100 to pre-attach the display panel 100 to the cover member 200-1. The external pressure PP1 is applied to the display panel 100 using a roller or a press machine, and thus the display panel 100 is pre-attached to the cover member 200-1. When the external pressure PP1 is applied to the display panel 100, i.e., when the display panel 100 is being pre-attached to the cover member 200-1, a first portion of air between the display panel 100 and the cover member 200-1 may be released through the through holes 200-1H.

Referring to FIG. 10E, the cover member 200-1 and the display panel 100, which are pre-attached to each other, are provided on the vacuum stage VS, which may perform vacuum suction and/or vacuum venting). In an embodiment, the process of attaching the display panel 100 to the cover member 200-1 may be performed on the vacuum stage VS.

The cover member 200-1 may be disposed on the vacuum stage VS such that at least one of the inner surfaces of the cover member 200-1 faces an upper direction. In an embodiment, the cover member 200-1 may be disposed on the vacuum stage VS such that the first surface IN1 faces the upper direction. The vacuum stage VS includes a plurality of stage surfaces respectively corresponding to the outer surfaces OT1, OT2, and OT3 of the cover member 200-1.

The cover member 200-1 is disposed to allow each of the outer surfaces OT1, OT2, and OT3 to face a corresponding stage surface of the stage surfaces. Each of the stage surfaces has an area enough to cover the corresponding outer surface of the outer surfaces OT1, OT2, and OT3.

In an embodiment, one or more of the outer surfaces OT1, OT2, and OT3 may be attached to corresponding stage surfaces. In an embodiment, one or more of the stage surfaces may be spaced apart from one or more corresponding ones of the outer surfaces OT1, OT2, and OT3 by one or more predetermined distances.

As illustrated in FIG. 10E, the vacuum stage VS includes at least one vacuum hole VS-H (or conduit VS-H) configured for venting air. The vacuum stage VS may apply a suction force PP2 to the cover member 200-1. Due to the suction force PP2, a second portion of the air existing between the display panel 100 and the cover member 200-1 may pass through the through holes 200-1H and then vented out of the vacuum stage VS through the vacuum hole VS-H.

If air existing between the display panel 100 and the cover member 200-1 were not substantially vented, the air might cause bubbles or wrinkles in the display device DP10, and the bubbles or wrinkles may cause substantial defects in the display device DP10. Embodiments of the invention may substantially prevent or minimize bubbles or wrinkles in the display device DP10.

The display panel 100 may be substantially uniformly attached to the cover member 200-1. In particular, although the cover member 200-1 has a complex shape that includes the portions PS, BS1, and BS2 with different orientations, the display panel 100 may be substantially uniformly attached to the cover member 200-1.

Analogously, a display panel 100 may be substantially uniformly attached to a cover member 200 (refer to FIG. 1) that has a flat plate shape, and a display panel 100 may be substantially uniformly attached to a cover member 200-2 (refer to FIG. 8) that has a curved surface, with use of the vacuum stage VS.

Referring to FIGS. 10F and 10G, the through holes 200-1H are covered (and sealed) in the process of forming the protective layer 300 on the other surface(s) of the cover member 200-1 (S300).

The protective member 300 may be formed through various methods. In an embodiment, the protective layer 300 may be provided in a liquid state. FIG. 10F illustrates a method of forming the protective layer 300 using a spray process.

As illustrated in FIG. 10F, coaters C10 may be disposed over the outer surfaces OT1, OT2, and OT3 of the cover member 200-1. The coaters C10 may spray a liquid material LQ onto the outer surfaces OT1, OT2, and OT3 of the cover member 200-1. During this process, a portion of the liquid material LQ may enter the through holes 200-1H.

The liquid material LQ may be transparent. The liquid material LQ may include a material that is able to protect the cover member 200-1H after being dried. In an embodiment, the liquid material LQ may include a heat-curable and/or light-curable resin. The liquid material LQ is coated on the outer surfaces OT1, OT2, and OT3 of the cover member 200-1 and is dried, and thus the protective layer 300 is formed.

The protective layer 300 may include a silicon-based compound and/or a fluorine-based compound. The silicon-based compound and/or the fluorine-based compound may prevent the surface of the protective layer 300 from being contaminated and/or may prevent fingerprints from remaining on the surface of the protective layer 300. In an embodiment, the protective layer 300 may have a diffuse reflection function (or property).

The liquid material LQ sprayed on the outer surfaces OT1, OT2, and OT3 of the cover member 200-1 is dried through a dry process to form the protective layer 300. The protective layer 300 covers the through holes 200-1H and protects the cover member 200-1.

The protective layer 300 may be formed using one or more of various methods, e.g., a spin coating method, a slit coating method, a dry etching process, etc.

A protective film 300-1 (refer to FIG. 4) may be provide instead of or in addition to a protective layer. In an embodiment, the protective film 300-1 may be provided on the cover member 200-1 and may be attached to the outer surface(s) of the cover member 200-1.

The process of attaching the protective film 300-1 to the cover member 200-1 may be performed using a lamination process that utilizes heat and/or pressure. The protective film 300-1 may have a substantially uniform thickness and may provide a substantially flat surface on the cover member 200-1.

The protective film 300-1 may be a synthetic resin film. The protective film 300-1 may be disposed on the outer surface(s) of the cover member 200-1. In an embodiment, an adhesive layer may be formed between the protective film 300-1 and the cover member 200-1 to enhance adhesion between the protective film 300-1 and the cover member 200-1.

Although embodiments of the present invention have been described, it is understood that the present invention should not be limited to these embodiments. Various changes and modifications can be made by one ordinary skilled in the art within the spirit and scope of the present invention as hereinafter claimed.

What is claimed is:

1. A display device comprising:
a display panel including a first display portion that is configured to display a first image according to a first signal;
a cover member overlapping the display panel, the cover member including a first cover portion and having a first through hole that extends through the first cover portion; and
a protective layer configured to cover the first through hole.

2. The display device of claim 1, wherein the first through hole is configured to overlap the first display portion.

3. The display device of claim 2, wherein the display panel including a plurality of the first through hole, the plurality of the first through hole are spread at the first display portion uniformly.

4. The display device of claim 3, wherein the first cover portion is substantially flat.

5. The display device of claim 3, wherein the first cover portion is substantially curved.

6. The display device of claim 1, wherein the display panel further includes a second display portion, the second display portion being configured to display a second image according to a second signal when the first display portion displays the first image, and
wherein an extension direction of the first display portion is different from an extension direction of the second display portion.

7. The display device of claim 6, wherein the cover member including a second cover portion and having a second through hole that extends through the second cover portion, and the second through hole overlapped with the second display portion.

8. The display device of claim 7, wherein the extension direction of the second display portion is substantially perpendicular to the extension direction of the first display portion.

9. The display device of claim 1, wherein the display panel is an organic light emitting display panel.

10. The display device of claim 1, wherein the display panel is a flexible display panel.

11. The display device of claim 1, the through hole has a circular shape when viewed in a cross section and the circular shape has a diameter equal to or smaller than about 5 micrometers.

12. The display device of claim 1, wherein the protective layer comprises a heat-curable resin or a light-curable resin.

13. The display device of claim 12, wherein the protective layer further comprises a silicon-based compound or a fluorine-based compound.

14. The display device of claim 13, wherein a portion of the protective layer fills in a portion of the through hole.

15. A method for manufacturing a display device, the method comprising:
forming a cover member, the cover member including a first cover portion and having a first through hole that extends through the first cover portion;
attaching a display panel to one surface of the cover member, the display panel including a first display portion that is configured to display a first image according to a first signal; and
forming a protective layer on another surface of the cover member, the protective layer covering the first through hole, and
wherein the first display portion is attached to the first cover portion.

16. The method of claim 15, wherein the first through hole is formed by irradiating a laser beam onto the cover member.

17. The method of claim 15, wherein the cover member further including a second cover portion having a second through hole extending the second cover portion,
wherein the display panel further including a second display portion that is configured to display a second image according to a second signal different from the first signal,
wherein the protective layer covers the first and the second through holes, and
wherein the second cover portion bent from the first cover portion, and the second display portion is attached to the second cover portion.

18. the attaching a display panel to one surface of the cover member comprises:
providing the cover member on a vacuum stage that includes a conduit;
pre-attaching the display panel to the one surface of the cover member; and
extracting an air between the cover member and the display panel through the first through hole and the conduit, so as to attach the display panel to the one surface of the cover member.

19. The method of claim 15, wherein the forming of the protective layer is performed by using a spraying method, a spin coating method, a slit coating method, or a deposition method.

20. The method of claim 15, wherein the forming of the protective layer comprises:
providing a synthetic resin film on the other surface of the cover member; and
attaching the synthetic resin film to the cover member.
